(19) United States
(12) Patent Application Publication
(10) Pub. No.: US 2005/0001231 A1
(43) Pub. Date: Jan. 6, 2005

(54) Light receiving element and light receiving device incorporating circuit and optical disc drive

(76) Inventors: Shigeki Hayashida, Kitakatsuragi-gun (JP); Tatsuya Morioka, Ikoma-shi (JP); Yoshihiko Tani, Tenri-shi (JP); Isamu Ohkubo, Kashiba-shi (JP); Hideo Wada, Kitakatsuragi-gun (JP)

Correspondence Address: BIRCH STEWART KOLASCH & BIRCH, PO BOX 747, FALLS CHURCH, VA, 22040-0747, US

(21) Appl. No.: 10/497,202

(22) PCT Filed: Dec. 10, 2002
(86) PCT No.: PCT/JP02/12905

(30) Foreign Application Priority Data
Dec. 26, 2001 (JP) 2001-394221

(51) Int. Cl. H01L 33/00

(52) U.S. Cl. 257/101

(57) ABSTRACT

A light receiving device includes a P type diffusion layer (101), a P type semiconductor layer (102), an N type diffusion layer (103) serving as a light receiving part, and a light transmitting film (104), all formed on a p type silicon substrate (100). The N type diffusion layer (103) has a thickness of 0.8 μm to 1.0 μm which is larger than an absorption length of incident light having wavelength of 400 nm, and such a concentration profile that a impurity concentration is not higher than 1E19 cm⁻³ on a surface and has a peak in a vicinity of the surface. Since recombination of carriers generated by the incident light is prevented in the vicinity of the surface of the N type diffusion layer (103), sensitivity of the light receiving device is enhanced and response speed is increased by the low-resistance N type diffusion layer (103) having a larger junction depth.

This Nonprovisional application claims priority under 35 U.S.C. §119(a) on Patent Application No. P2001-394221 filed in Japan on Dec. 26, 2001, the entire contents of which are hereby incorporated by reference.

### TECHNICAL FIELD

The present invention relates to a light receiving device, a light receiving unit incorporating a circuit, and an optical disk drive.

### BACKGROUND ART

Conventionally, optical disk drives for optical disks such as CDs (Compact Discs) and DVDs (Digital Versatile Disks) are provided with an optical pickup. The optical pickup includes a semiconductor laser device for emitting a light beam to be radiated to an optical disk and a light receiving device for receiving a reflected light beam radiated to and reflected by the optical disk. In recent years, higher-density DVDs are being vigorously developed, which demands for processing large-volume data such as dynamic images and for higher read rates such as 12X. Since an amount of a data storage capacity of the optical disk such as the above-stated DVDs is inversely proportional to the square volume of a wavelength of radiated light, an attempt to shorten the wavelength of the light emitted from the semiconductor laser device in the pickup system is being pursued.

In the above pickup system, with the shorter wavelength of the light emitted from the semiconductor laser device, the light receiving device is required to convert incident light to an electronic signal at high efficiency. In other words, it is necessary to enhance the sensitivity of the light receiving device to the incident light. The sensitivity of the light receiving device is indicated by the following formula:

$$Sensitivity = \frac{photocurrent}{Intensity of incident light} = \frac{{I}_{ph}}{{P}_{i0}} = \frac{q}{{h}_{c} / λ} η \qquad ( 1 - R )$$

wherein “q” denotes an elementary quantity of electric charge, “h” denotes a Planck's constant, “λ” denotes a wavelength of incident light, “c” denotes a light speed, “η” denotes a quantum yield, and “R” denotes a surface reflectance of the device that is a ratio of reflected light on the surface of the light receiving device to incident light.

In the light receiving device, minority carriers generated by incident light can be taken out as electric current at high efficiency if the carriers are generated in the vicinity of a PN junction part, which is formed for forming electric fields at a specified depth position from the light incidence surface of the device. Herein, if light with the intensity Pᵢ₀ is incident to a medium, the light intensity Pᵢ(x) at a depth x in the medium from the incidence surface is obtained as follows:
−dPᵢ(x)=α₀ Pᵢ(x)dx (1)
−dPᵢ(x)/dx=−α₀ Pᵢ(x) (2)
therefore,
Pi(x)=Pᵢ₀ exp(−α₀ x) (3)
where “α₀” is an absorption coefficient, which is a physical constant that varies depending on both the medium and wavelength of light. Light radiated to the surface of the medium such as semiconductors comes into the medium while being absorbed thereby, and its light intensity in the medium is exponentially decreased depending on the depth from the surface as shown in the formula (3). Light with a wavelength having larger absorption coefficient α₀ is absorbed by the medium at closer position to the surface, resulting in generation of carriers. A distance Lₐ between the surface of the medium from which light is incident and a point in the depth direction of the medium at which the light arrives is defined as below based on the formula (2):
α₀ Pi₀ Lₐ=∫^{∞}₀α₀ Pᵢ₀ exp(−α₀ x)dx
hence, La=1/α₀
Herein, the value Lₐ that is defined as the inverse number of an absorption coefficient α₀ is referred to as an absorption length, and the intensity of incident light at this position is expressed as exp(−1). For example, red incident light with a wavelength of about 600 nm has an absorption coefficient α₀ of about 3000 cm⁻¹ and an absorption length of 3 μm, while blue-violet incident light with a wavelength of about 400 nm has a considerably large absorption coefficient α₀ of about 50000 cm⁻¹, and a small absorption length of 0.2 μm.

This indicates that the light receiving device for receiving short wavelength light needs to have a PN junction provided at a depth position smaller than the absorption length of the incident light in order to gain a sufficient sensitivity.

FIG. 14 is a view showing a conventional light receiving device (see Japanese unexamined patent application No. H09-237912). This light receiving device is composed of a low-resistance N type diffusion layer 501 and an N type semiconductor layer 502, each formed on a P type semiconductor substrate 500. On the surface of the N type semiconductor layer 502, there is formed a first P type diffusion layer 503 functioning as a light receiving part, by which a PN junction is obtained. Reference numeral 504 denotes a second P type diffusion layer with high concentration to reduce the resistance of the P type diffusion layer 503. Reference numeral 505 denotes an N type high-concentration diffusion layer, which is in contact with the low-resistance N type diffusion layer 501. Reference numeral 506 is an insulating film. The PN junction is formed at an extremely shallow position of 0.01 to 0.2 μm so that the concentration of the first P type diffusion layer 503 is from 1E16 cm⁻³ to 1E20 cm⁻³ and that a junction depth is smaller than the absorption length of the wavelength of received light. Thus, the sensitivity, particularly to light with a wavelength of not larger than 500 nm, is enhanced.

However, the conventional light receiving device has a problem that the junction depth is so small that the response speed is declined. For example, with the junction depth of less than 0.2 μm, the resistance is higher than that with the junction depth of 1.0 μm by approx. 1/10, resulting in drastic deterioration of the response speed. If impurity concentration on the surface part of the light receiving device is increased to prevent rise of the resistance, recombination of carriers on the surface part becomes outstanding, thereby causing reduced sensitivity.

If the junction depth of the light receiving device is increased to prevent decline of the response speed, and light received by the light receiving device has short wavelength, then most part of the carriers are absorbed by the surface part of the light receiving device, causing deteriorated sensitivity. Further, if a high-concentration diffusion layer is additionally provided to reduce resistance as with the case of the conventional light receiving device, a light receiving area is enlarged and so the capacitance is increased, thereby causing deteriorated response speed. More specifically, increase of speed and enhancement of the sensitivity of the light receiving device are in trade-off relation, and particularly in the case where light with short wavelength is received for an attempt of further speedup of optical disks, achieving both increased speed and enhanced sensitivity is extremely difficult.

Accordingly, it is a primary object of the present invention to provide a light receiving device that achieves both higher speed and higher sensitivity.

### DISCLOSURE OF THE INVENTION

In order to achieve the above object, the present invention provides a light receiving device comprising:
a first conductivity type semiconductor layer; and
a second conductivity type semiconductor layer on the first conductivity type semiconductor layer, wherein
a thickness of the second conductivity type semiconductor layer is larger than an absorption length of light incident to the second conductivity type semiconductor layer, and
the second conductivity type semiconductor layer has impurity concentration of not smaller than 1E17 cm⁻³ and not larger than 1E19 cm⁻³ in a vicinity of a surface of the second conductivity type semiconductor layer.

According to the above configuration, although the thickness of the second conductivity type semiconductor layer is larger than the absorption length of incident light to the semiconductor layer, and a junction between the first conductivity type semiconductor layer and the second conductivity type semiconductor layer is placed at a relatively deep position, the impurity concentration in the vicinity of the surface of the second conductivity type semiconductor layer is not smaller than 1E17 cm⁻³ and not larger than 1E19 cm³. Consequently, in the vicinity of the surface of the second conductivity type semiconductor layer, recombination of carriers is effectively reduced, resulting in enhanced sensitivity of the light receiving device. Here, if the impurity concentration in the vicinity of the surface of the second conductivity type semiconductor layer is smaller than 1E17 cm⁻³, the resistance of the semiconductor layer is increased and therefore the response of the light receiving device is deteriorated. If the impurity concentration in the vicinity of the surface of the second conductivity type semiconductor layer is larger than 1E19 cm⁻³, recombination of carriers in the vicinity of the surface of the semiconductor layer is increased, thereby causing deterioration of the sensitivity of the light receiving device.

Moreover, since the thickness of the second conductivity type semiconductor layer is larger than the absorption length of incident light to the semiconductor layer, the resistance is lower than that in the case of a conventional semiconductor layer whose thickness is smaller than the absorption length of incident light, so that the light receiving device is able to achieve higher response speed than that of conventional one. Therefore, the light receiving device makes it possible to obtain high performance by achieving both enhanced sensitivity and increased response speed.

The light receiving device comprising a first conductivity type semiconductor layer and a second conductivity type semiconductor layer on the first conductivity type semiconductor layer herein refers to any form of light receiving device such as those having second conductivity type impurity diffused over a surface part of a first conductivity type semiconductor layer to form a second conductivity type semiconductor layer, and those having a second conductivity type semiconductor layer laminated on a first conductivity type semiconductor layer.

The light receiving device of the present invention allows effective enhancement of sensitivity and response speed particularly when receiving red light with a wavelength of about 600 nm or less. When receiving the red light with a wavelength of about 600 nm or less, the conventional light receiving device could not achieve both enhanced sensitivity and increased response speed even if a junction depth is decreased to improve the sensitivity and impurity concentration is increased to increase the response speed.

The inventor of the present invention found out through various experiments that enhanced sensitivity is achievable by controlling an in-depth profile of impurity concentration even if a junction is formed at a deep position contrary to the case of the conventional light receiving device, and hence invented the present invention based on this founding.

Furthermore, a light receiving device of the present invention comprises:
a first conductivity type semiconductor layer; and
a second conductivity type semiconductor layer on the first conductivity type semiconductor layer, wherein
a thickness of the second conductivity type semiconductor layer is larger than an absorption length of light incident to the second conductivity type semiconductor layer, and
the second conductivity type semiconductor layer has impurity concentration of not smaller than 1E17 cm⁻³ and not larger than 1E19 cm⁻³ at a position which is distant form a surface of the second conductivity type semiconductor layer in a thickness direction at a distance almost equal to the absorption length of the light.

According to the above configuration, the impurity concentration of the second conductivity type semiconductor layer is not smaller than 1E17 cm⁻³ and not larger than 1E19 cm ⁻³ at the position which is distant form the surface of the second conductivity type semiconductor layer in the thickness direction at the distance almost equal to the absorption length of the light. Thus recombination of carriers generated in the vicinity of the surface of this second conductivity type semiconductor layer is effectively prevented, which enhances the sensitivity of the light receiving device. Therefore, even with the thickness of the second conductivity type semiconductor layer being larger than the absorption length of the light, excellent sensitivity is achieved while response speed can be increased.

Herein, if the impurity concentration of the second conductivity type semiconductor layer is smaller than 1E17 cm⁻³ at the position which is distant form the surface of the second conductivity type semiconductor layer in the depth direction at the distance almost equal to the absorption length of the light, then the resistance of the semiconductor layer is increased and response of the light receiving device is deteriorated. If the impurity concentration of the second conductivity type semiconductor layer is larger than 1E19 cm⁻³ at the position which is distant form the surface of the second conductivity type semiconductor layer in the thickness direction at the distance almost equal to the absorption length of the light, then recombination of carriers at the position with large impurity concentration is increased and the sensitivity of the light receiving device is degraded.

In one embodiment, the second conductivity type semiconductor layer has a peak impurity concentration on the surface.

According to the above-mentioned embodiment, the second conductivity type semiconductor layer has the peak impurity concentration on the surface, so that carriers generated by light incident to the second conductivity type semiconductor layer are effectively prevented from recombining in the vicinity of the surface of this semiconductor layer. Therefore, most of the carriers generated by the incident light can reach the junction part, as a result of which the light receiving device can achieve sufficient sensitivity.

Furthermore, a light receiving unit incorporating a circuit of the present invention comprises:
the aforementioned light receiving device; and
a signal processing circuit for processing a signal from the light receiving device, wherein
the light receiving device and the signal processing circuit are formed on an identical substrate.

According to the above configuration, the light receiving device and the signal processing circuit are formed monolithically so that a small-size light receiving unit having excellent sensitivity and high response speed is attained.

Furthermore, an optical disk drive of the present invention comprises the aforementioned light receiving device or the aforementioned light receiving unit incorporating a circuit.

According to the above configuration, the light receiving device or the light receiving unit incorporating a circuit having excellent sensitivity and high response speed is used, thus, an optical disk drive particularly suitable for read and write access to a mass storage optical disk with use of light with a short wavelength is provided.

### BRIEF DESCRIPTION OF THE DRAWINGS

FIG. 1A is a plan view showing a light receiving device in a first embodiment of the present invention, while FIG. 1B is a cross sectional view taken along the line and shown by arrows A-A′ in FIG. 1A;

FIG. 2 is a graph showing the relation between impurity concentration in the vicinity of the surface of a light receiving part and sensitivity of the light receiving device in the first embodiment;

FIG. 3 is a graph showing the relation between impurity concentration in the vicinity of the surface of the light receiving part and cathode resistance of the light receiving part of the light receiving device in the first embodiment;

FIG. 4 is a graph showing the relation between the cathode resistance of the light receiving part and response speed of the light receiving device in the first embodiment;

FIG. 5 is a graph showing an impurity concentration profile of the light receiving part of the light receiving device in the first embodiment;

FIG. 6 is a plan view showing a light receiving device in the first embodiment provided with a plurality of cathode electrodes 108;

FIG. 7 is a graph showing an impurity concentration profile of the light receiving part of the light receiving device in the second embodiment;

FIG. 8 is a graph showing the relation between impurity concentration in the vicinity of the surface of a light receiving part and sensitivity of the light receiving device in the second embodiment;

FIG. 9 is a graph showing the relation between impurity concentration in the vicinity of the surface of the light receiving part and cathode resistance of the light receiving part of the light receiving device in the second embodiment;

FIG. 10 is a cross sectional view showing a light receiving device in a third embodiment of the present invention;

FIG. 11 is a graph showing an impurity concentration profile of the light receiving part of the light receiving device in the third embodiment;

FIG. 12 is a cross sectional view showing a light receiving unit incorporating a circuit in a fourth embodiment of the present invention;

FIG. 13 is a view showing an optical disk drive in a fifth embodiment of the present invention; and

FIG. 14 is a cross sectional view showing a conventional light receiving device;

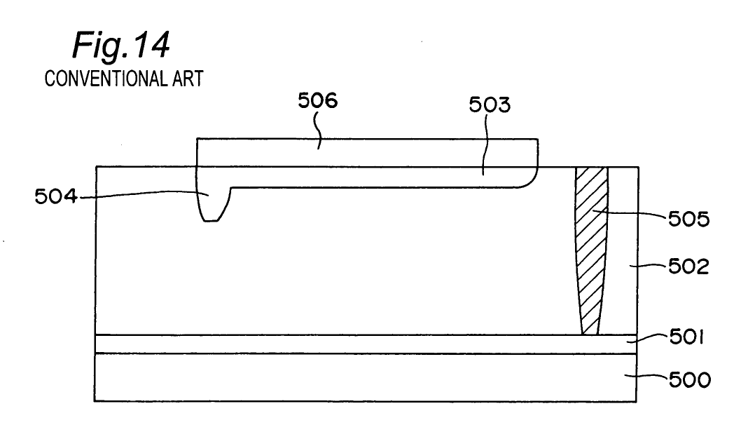

### BEST MODE FOR CARRYING OUT THE INVENTION

Embodiments of the invention will now be described in detail with reference to the accompanying drawings.

(FIRST EMBODIMENT)

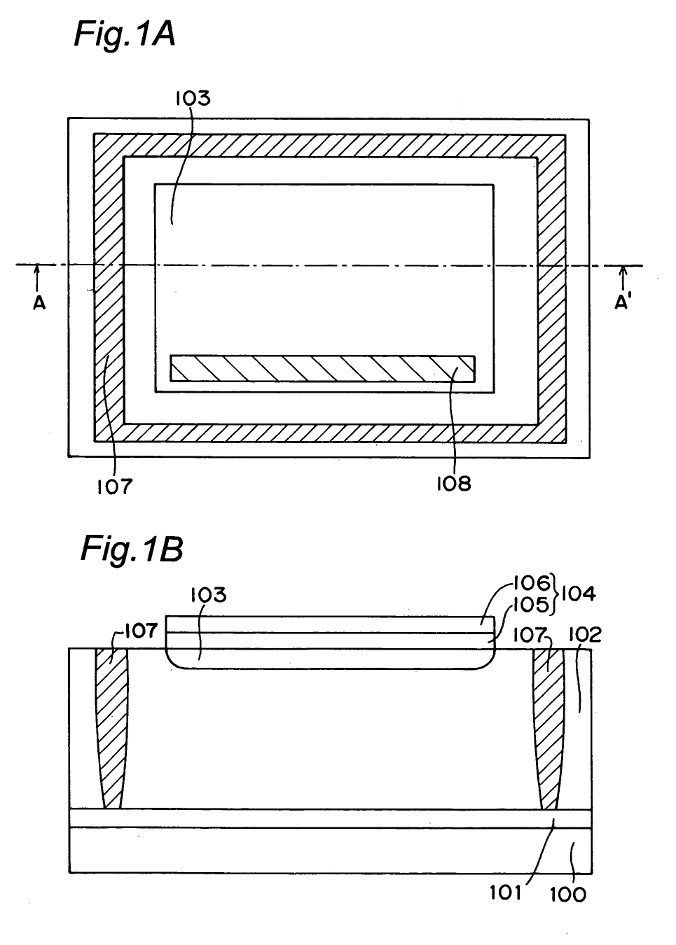

FIG. 1A is a plan view showing a light receiving device in a first embodiment of the present invention, while FIG. 1B is a cross sectional view taken along the line and shown by arrows A-A′ in FIG. 1A. It is noted that in the present embodiment, multilevel interconnections and interlayer films formed after the step for processing metal interconnections are deleted.

As shown in FIG. 1B, the light receiving device has a P type diffusion layer 101 with impurity concentration of about 1E18 cm⁻³ and a thickness of about 1 μm on a P type silicon substrate 100, and on top surface of the P type diffusion layer 101, has a P type semiconductor layer 102 as a first conductivity type semiconductor layer with impurity concentration of 1E13 cm⁻³ to 1E15 cm⁻³ and a thickness of about 10 μm to 20 μm. In the vicinity of the surface of the P type semiconductor layer 102, there is formed an N type diffusion layer (cathode) 103 as a second conductivity type semiconductor layer serving as a light receiving part. An impurity forming this N type diffusion layer 103 is a pentavalent impurity such as P (phosphorous). On the N type diffusion layer 103, there is disposed a light transmitting film 104 as an antireflection film, which is composed of a silicon oxide 105 and a silicon nitride 106. The film thickness of the silicon oxide 105 and the silicon nitride 106 is so set as to have the lowest reflectance to light that comes incident to the light receiving device. More specifically, if the wavelength of the incident light to the light receiving device is 400 nm, the thickness of the silicon oxide 105 is set at 10 nm to 30 nm while the thickness of the silicon nitride 106 is set at 20 nm to 50 nm. It is to be noted that without being limited to two layers, the light transmitting film 104 may be composed of a singularity of layer or a plurality of layers not smaller than 3 layers. Further, without being limited to the silicon oxide or silicon nitride, the light transmitting film 104 may be composed of any material.

Reference numeral 107 denotes a P type diffusion layer for pulling out an anode electrode, which is formed so as to extend from the top surface of the P type semiconductor layer 102 to the P type diffusion layer 101. The P type diffusion layer 107 has impurity concentration of around 5E19 cm⁻³ to 1E21 cm⁻³ in the vicinity of the surface. Reference numeral 108 denotes an electrode pulled out from a cathode, i.e., the N type diffusion layer 103.

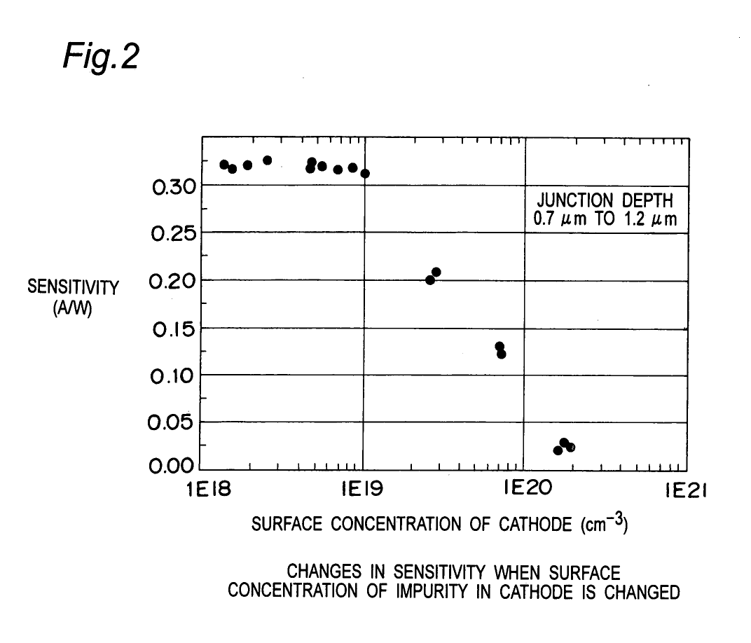

The layer thickness, i.e., the junction depth of the PN junction as well as surface impurity concentration of the N type diffusion layer 103 are so set as to obtain excellent sensitivity and response speed of this light receiving device. FIG. 2 is a graph showing changes in sensitivity of a light receiving device having a junction depth of 0.7 μm to 1.2 μm to incident light with a wavelength of 400 nm when surface concentration of impurity in the cathode is changed. The horizontal axis of FIG. 2 represents the surface concentration (cm⁻³) of cathode in the light receiving part while the vertical axis represents sensitivity (A/W). As shown in FIG. 2, when the light received by the light receiving device has a wavelength of about 400 nm, keeping the surface impurity concentration of the N type diffusion layer 103 to not larger than 1E19 cm⁻³ makes it possible to obtain excellent sensitivity with 90% or more quantum efficiency even though the junction depth is larger than the absorption length of incident light. Here, in an impurity concentration profile of the N type diffusion layer 103, if a peak of the impurity concentration is present at a relatively deep position near the junction, then recombination of carriers occurs in the vicinity of the surface of the N type diffusion layer 103. Consequently, the percentage of the carriers that fail to reach the junction among the carriers generated in the vicinity of the surface of the N type diffusion layer 103 may increase and therefore cause degradation of the sensitivity of the light receiving device. In order to prevent such degradation of the sensitivity, a peak concentration in the impurity concentration profile should preferably be placed on the surface of the N type diffusion layer 103.

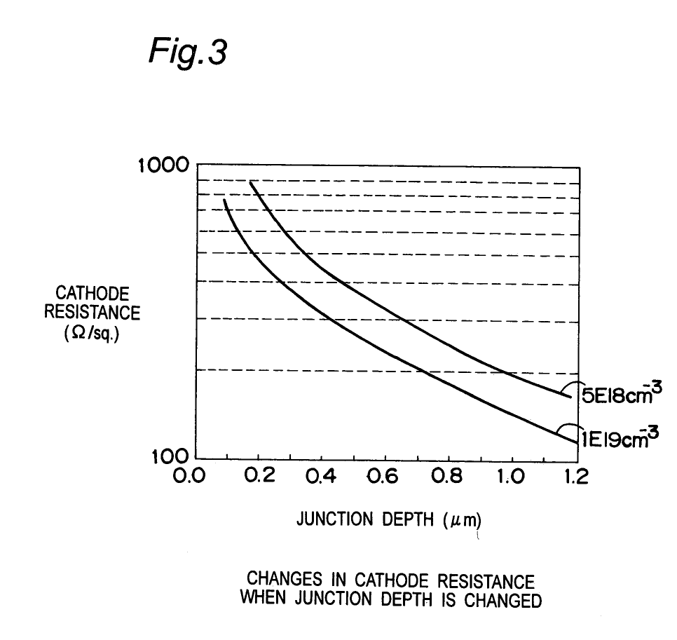

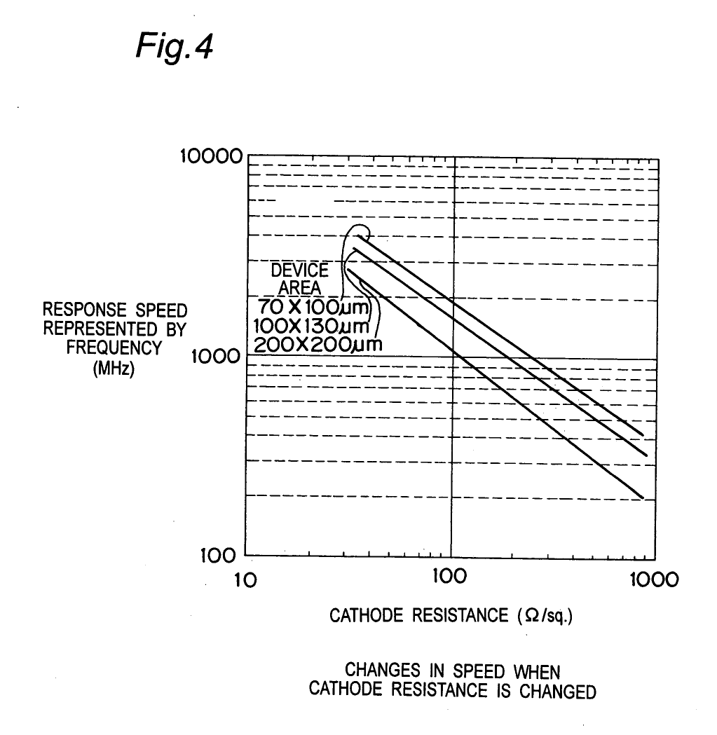

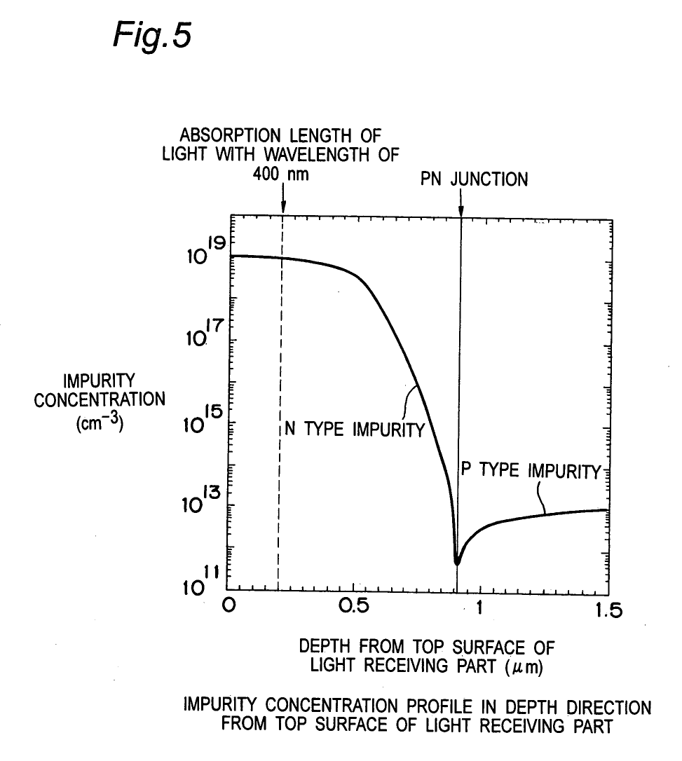

By setting the layer thickness of the N type diffusion layer 103 , i.e., the junction depth at about 0.8 μm to 1.0 μm, further excellent response speed is obtained. FIG. 3 is a view showing changes in cathode resistance when the junction depth is changed, where the horizontal axis represents a junction depth (μm) while the vertical axis represents cathode resistance (Ω/sq.). As shown in FIG. 3, when the impurity concentration in the vicinity of the surface of the N type diffusion layer 103 is 1E19 cm⁻³, setting the junction depth at about 0.8 μm to 1.0 μm enables sheet resistance of the N type diffusion layer 103 to be not larger than 200 Ω/sq. FIG. 4 is a view showing changes in response speed when the cathode resistance is changed, where the horizontal axis represents cathode resistance (Ω/sq.) while the vertical axis represents response speed represented by frequency (MHz). As shown in FIG. 4, setting the cathode resistance to not larger than 200 Ω/sq. enables the light receiving device with a device area of about 70 μm×100 μm to have a response speed of not smaller than 1 GHz. Further, with an device area of about 200 μm×200 μm, the response speed can be 500 MHz or more. Furthermore, in the case where the impurity concentration in the vicinity of the surface is about 5E18 cm ⁻³, a response speed equal to that in the case where the impurity concentration is 1E19 cm⁻³ can be obtained by setting the junction depth at about 1.0 μm to 1.2 μm. FIG. 5 is an example of an impurity concentration profile to be formed for the N type diffusion layer 103 when the surface concentration thereof is 1E19 cm⁻³. In FIG. 5, the horizontal axis represents a depth (μm) from the surface of the light receiving part while the vertical axis represents impurity concentration (cm⁻³). For comparison with the PN junction depth, the adsorption length of light with wavelength of 400 nm is also superimposed.

The above-configured light receiving device operates as follows. That is, once the light receiving device receives light, the light transmits through the light transmitting film 104 and comes incident to the N type diffusion layer 103 almost without being reflected by the surface of the N type diffusion layer 103. When the light comes incident to the N type diffusion layer 103, carriers are generated. Since the N type diffusion layer 103 is so formed that the impurity concentration on the surface is 1E19 cm⁻³ and the impurity concentration is peaked on the surface, recombination of the carriers in the vicinity of the surface of the N type diffusion layer 103 is mostly prevented. Consequently, most of the carriers reach the junction between the P type semiconductor layer 102 and the N type diffusion layer 103. As a result, the light receiving device obtains excellent sensitivity. Moreover, since the N type diffusion layer 103 has a thickness of 0.8 μm to 1.0 μm, and therefore its resistance is relatively low, the light receiving device is provided with more excellent frequency response and implements high-speed operation. More specifically, the light receiving device of the present embodiment achieves both enhanced sensitivity and increased speed. The light receiving device is particularly suitable for receiving light with short wavelength of 600 nm or less. Further, it is not necessary to additionally provide a high-concentration diffusion layer for reducing resistance as with the conventional case, so that it is possible to make the area of the light receiving part small and lessen a size of the light receiving device.

In the above embodiment, an impurity used in the N type diffusion layer 103 is not limited to phosphorous as long as it is pentavalent.

Further in the above embodiment, P type and N type conductivity may be interchanged to each other.

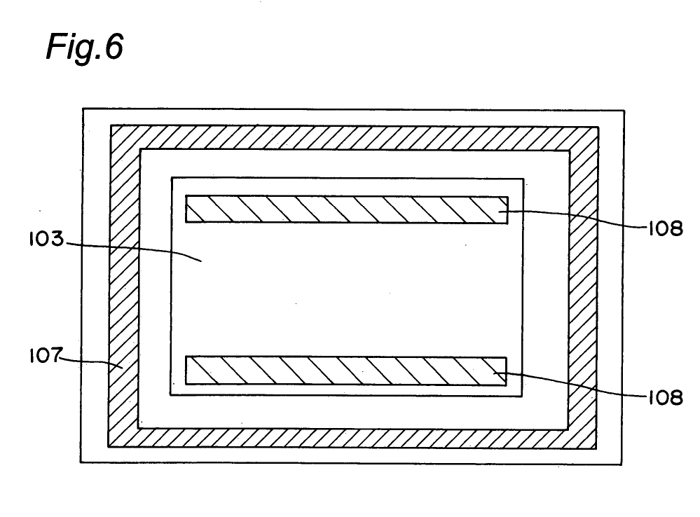

Furthermore, as shown in FIG. 6, a plurality of cathode electrodes 108 may be provided for reducing the resistance. The light receiving device may be a split type light receiving device having a plurality of light receiving parts. In this case, no restriction is placed on the form, the number or the forming method of the light receiving parts.

Further, the impurity concentration and the layer thickness of the P type diffusion layer 101 and the P type semiconductor layer 102 are not limited to those disclosed in the present embodiment. It is also possible to delete the P type diffusion layer 101 and the P type semiconductor layer 102, and instead, an N type diffusion layer is directly formed on the P type substrate 100 to form the PN junction.

(SECOND EMBODIMENT)

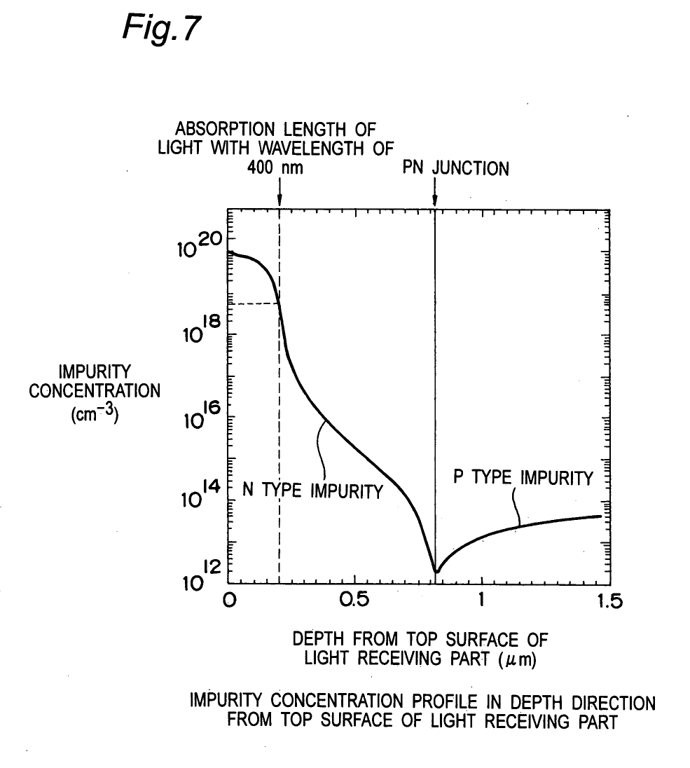

FIG. 7 is a graph showing an impurity concentration profile of an N type diffusion layer as a second conductivity type semiconductor layer and a P type semiconductor layer as a first conductivity type semiconductor layer of a light receiving device in the second embodiment of the present invention. The N type diffusion layer forms a light receiving part while the P type semiconductor layer contacts the N type diffusion layer. In the N type diffusion layer that forms the light receiving part, As (arsenic) is used as an impurity. The concentration profile shown in FIG. 7 is formed by detecting the impurity concentration with SIMS (Secondary Ion Mass Spectrometer).

The light receiving device in the second embodiment has the same configuration as the light receiving device in the first embodiment except the point that the impurity of the N type diffusion is As. In this embodiment, description is made with use of the reference numerals identical to those used for the light receiving device in the first embodiment shown in FIGS. 1A and 1B.

The light receiving device of the present invention has an impurity concentration profile in which the concentration is not larger than 1E19cm⁻³ in a depth of approximately the same length as the adsorption length of incident light from the top surface of the N type diffusion layer 103. In this embodiment, the incident light has wavelength of 400 nm, the thickness of the N type diffusion layer 103 , i.e., the junction depth is 0.8 μm, and the surface impurity concentration of the N type diffusion layer 103 is 1E20cm⁻³. The light receiving device of the present embodiment also has a peak impurity concentration in the vicinity of the surface like the first embodiment.

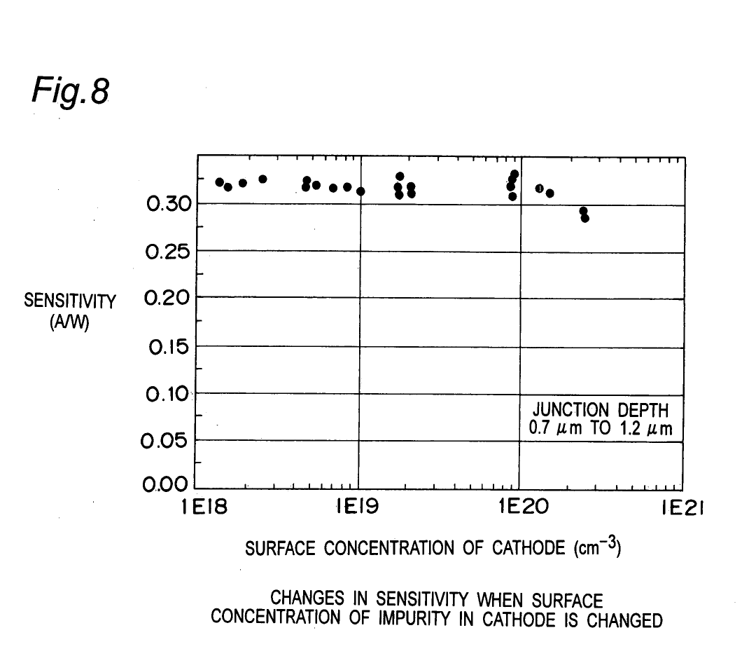

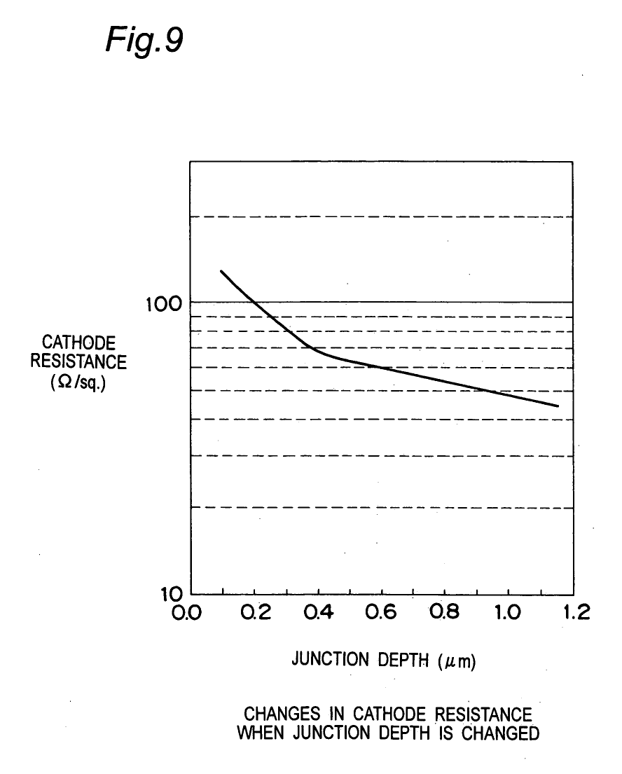

FIG. 8 is a graph showing changes in sensitivity of the light receiving device when impurity concentration in the vicinity of the surface of an N type diffusion layer 103, that is a cathode in a light receiving part. In FIG. 8, the horizontal axis represents surface concentration (cm⁻³) while the vertical axis represents sensitivity (A/W). As shown in FIG. 8, when the impurity concentration in the vicinity of the surface of the N type diffusion layer 103 is about 1E20 cm⁻³ or less, the light receiving device obtains an excellent sensitivity characteristic. Here, it is not necessary to make a junction position between the N type diffusion layer 103 and the P type semiconductor layer 102 shallow like the conventional case, and therefore the junction position is deepened so as to reduce sheet resistance. This makes it possible to provide a light receiving device which can achieve both enhanced sensitivity and response. FIG. 9 is a graph showing changes in cathode resistance when a junction depth is changed. In FIG. 9, the horizontal axis represents a junction depth (μm) while the vertical axis represents cathode resistance Ω/sq.). As shown in FIG. 9, when the junction depth is about 0.8 μm, the sheet resistance or the cathode resistance of the N type diffusion layer 103 is about 50Ω/sq., which enables the response speed of the light receiving device to be not smaller than 1GHz. More specifically, even if the impurity concentration in the vicinity of the surface of the N type diffusion layer 103 is increased to about 1E20 cm⁻³ for reducing resistance, excellent sensitivity as well as higher speed can be obtained by setting the concentration at a position from the surface of the N type diffusion layer 103 almost equal to the absorption length of incident light to not larger than 1E19 cm⁻³. Particularly, the light receiving device in the present embodiment achieves effective enhancement of both the sensitivity and the response speed when it receives light with short wavelength of 600 nm or less.

In the above embodiment, although arsenic is used as an impurity in the N type diffusion layer 103, other pentavalent impurities may be acceptable if the profile same as shown in FIG. 7 is still formed.

(THIRD EMBODIMENT)

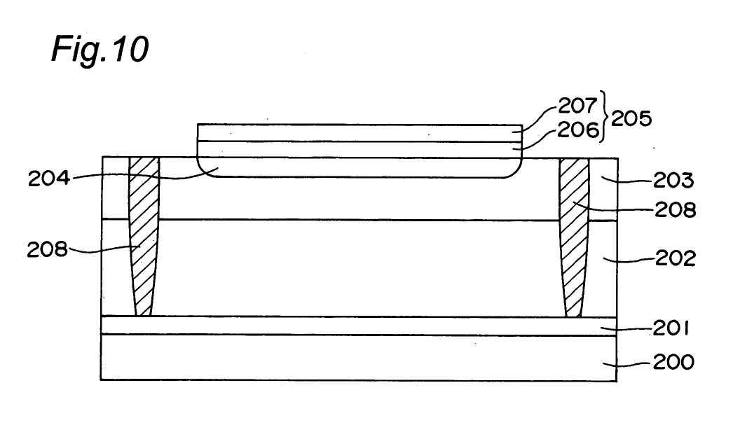

FIG. 10 is a cross sectional view showing a light receiving device in a third embodiment of the present invention. It is noted that in the present embodiment, multilevel interconnections and interlayer films formed after the step for processing metal interconnections are deleted.

The light receiving device of the present embodiment has a P type diffusion layer 201 with impurity concentration of about 1E18 cm⁻³ and a thickness of about 1 μm formed on a P type silicon substrate 200, and has a P type semiconductor layer 202 as a first conductivity type semiconductor layer with impurity concentration of about 1E13 cm⁻³ to 1E15 cm⁻³ and a thickness of about 10 μm to 20 μm formed on the P type diffusion layer 201. Reference numeral 203 is an N type semiconductor layer. Reference numeral 204 is an N type diffusion layer as a second conductivity type semiconductor layer with an impurity diffused for reducing resistance, and the impurity concentration in the vicinity of the surface is set to about 1E18 cm⁻³ to 1E20 cm⁻³ while a thickness thereof is set at about 1 μm to 2 μm. It is to be noted that when the impurity concentration in the vicinity of the surface of the N type diffusion layer 204 is set to not smaller than 1E19 cm⁻³, the impurity concentration at a depth almost equal to the absorption length of the wavelength of incident light is set to not larger than 1E19 cm⁻³. In this case, an impurity of the N type diffusion layer 204 may be any element such as P, As and Sb (antimony) as long as the element is pentavalent. Further, the N type diffusion layer 204 preferably has an impurity concentration peak on the surface of the N type diffusion layer 204. Reference numeral 205 denotes a light transmitting film as an antireflection film, which is composed of a silicon oxide 206 and a silicon nitride 207 as with the first embodiment. The N type semiconductor layer 203 and the P type semiconductor layer 202 constitute an NP junction. Reference numeral 208 is a P type diffusion layer for pulling out an electrode from the anode.

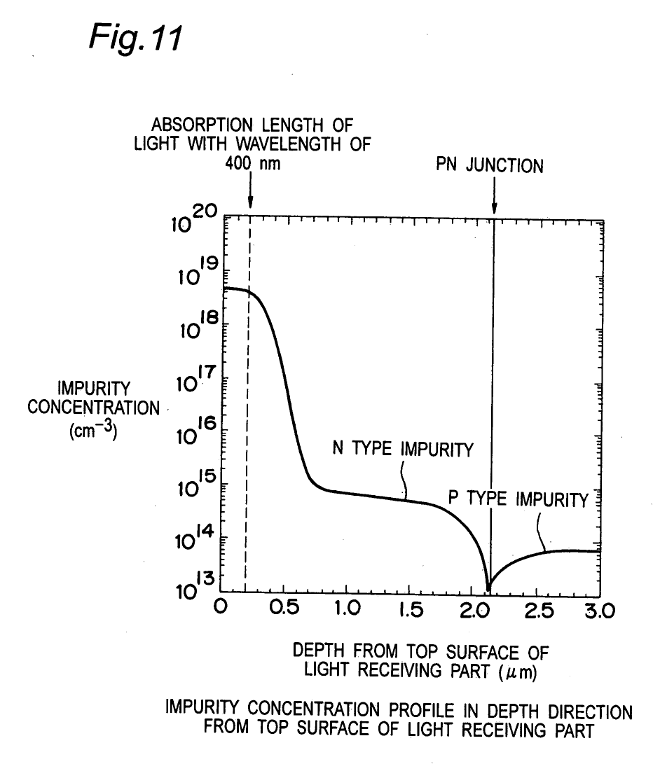

FIG. 11 is a graph showing an impurity concentration profile of the N type diffusion layer 204, the N type semiconductor layer 203, and part of the P type semiconductor layer 202 in the above light receiving device. This impurity concentration profile is the one that can most effectively improve sensitivity and response speed even when light with wavelength of 400 nm is received. Although the light receiving device having this impurity concentration profile has a very large junction depth of about 2.0 μm, excellent sensitivity is still achievable because the impurity concentration at a depth almost identical to the absorption length of incident light is not larger than 1E19 cm⁻³. Further, the resistance is as low as 50 Ω/sq., by which excellent response speed is also attainable in this embodiment. The light receiving device in this embodiment can enhance sensitivity and response speed particularly when receiving light with short wavelength of 600 nm or less.

(FOURTH EMBODIMENT)

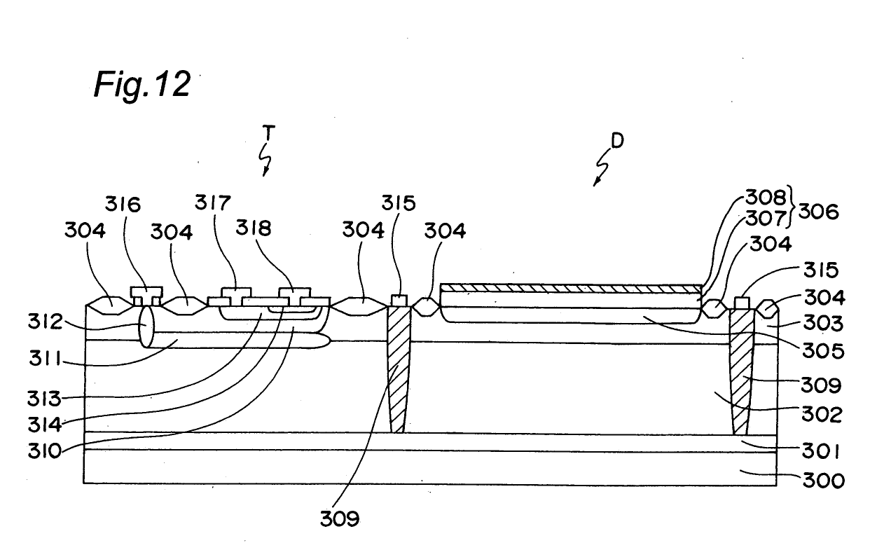

FIG. 12 is a cross sectional view showing a light receiving unit incorporating a circuit in a fourth embodiment of the present invention. In the light receiving unit incorporating a circuit, a light receiving device D of the present invention and a bipolar transistor T as a signal processing circuit for processing a signal from the light receiving device D are formed on the same semiconductor substrate. In the present embodiment, multilevel interconnections and interlayer films formed after the step for processing metal interconnections are deleted.

The light receiving unit incorporating a circuit in the present embodiment has a P type diffusion layer 301 with a thickness of about 1 to 2 μm and impurity concentration of about 1E18 to 1E19 cm⁻³ formed on a P type silicon substrate 300 with impurity concentration of about 1E15 cm⁻³. On this P type diffusion layer 301, there is formed a first P type semiconductor layer 302 with a thickness of about 10 μm to 16 μm and impurity concentration of 1E13 to 1E14 cm⁻³. On this first P type semiconductor layer 302, there is formed a second P type semiconductor layer 303 with a thickness of about 1 to 2 μm and impurity concentration of about 1E13 to 1E14 cm⁻³. On this second P type semiconductor layer 303, there is formed a LOCOS region 304 for separating the device.

In the light receiving device D part of the light receiving unit incorporating a circuit, an N type diffusion layer 305 as a second conductivity type semiconductor layer with impurity concentration of about 1E18 to 1E20 cm⁻³ and a thickness of about 0.8 to 1.2 μm is formed in the second P type semiconductor layer 303 as a first conductivity type semiconductor layer. The N type diffusion layer 305 constitutes a cathode of the light receiving device. An impurity of the N type diffusion layer 305 may be any element such as P, As and Sb as long as the element is pentavalent. This impurity forms an impurity concentration profile as with the case of the light receiving devices in the first and the second embodiments. By this, both increased speed and enhanced sensitivity of the light receiving device D is achieved.

Further, at least in a region on the second P type semiconductor layer 303 to which light is radiated, there is provided a light transmitting film 306 as an antireflection film. This light transmitting film 306 is composed of a silicon oxide 307 with a thickness of 16 nm and a silicon nitride 308 with a thickness of about 30 nm, each disposed in this order from the side of the second P type semiconductor layer 303.

Further, there is provided a second P type diffusion layer 309 extending in a thickness direction from the top surface of the second P type semiconductor layer 303 to the surface of the first P type diffusion layer 301 through the second P type semiconductor layer 303 and the first P type semiconductor layer 302. The second P type diffusion layer 309 is formed from B (boron) with concentration of about 1E18 to 1E19 cm⁻³. Through this second P type diffusion layer 309, interconnections formed on the surface of the light receiving unit incorporating a circuit are electrically connected to the first P type diffusion layer 301.

In the transistor T part of the light receiving unit incorporating a circuit, an N type well structure 310 made of P (phosphorus) with concentration of about 1E17 to 1E19 cm⁻³ is formed in the second P type semiconductor layer 303. In order to reduce resistance of this N type well structure 310, an N type diffusion layer 311 made of P (phosphorus) with concentration of about 1E18 to 1E19 cm⁻³ is provided below the N type well structure 310. In part of the region of the N type well structure 310, there is formed an N type diffusion layer 312 made of phosphorus with concentration of about 1E19 to 2E19 cm⁻³ serving as a collector contact of the transistor. Further, in part of the region of the N type well structure 310, there are formed a P type diffusion layer 313 made of B (boron) with concentration of about 1E17 to 1E19 cm⁻³ serving as a base of the transistor and an N type diffusion layer 314 made of As serving as an emitter.

Further, there are formed a cathode electrode (unshown) for pulling out an electrode from the N type diffusion layer 305 of the light receiving device D, an anode electrode 315 connected to the P type diffusion layer 309, as well as a collector electrode 316, a base electrode 317, and an emitter electrode 318 of the transistor.

The above-configured light receiving unit incorporating a circuit has the light receiving device D which can effectively achieve both a sensitivity characteristic and a response characteristic, and is particularly suitable for receiving light with short wavelength.

In the above embodiment, although an NPN transistor is used, a PNP transistor or the both transistors may be formed on the substrate.

Further, without being limited to the configuration defined in the present invention, the transistor T may employ other configurations.

Furthermore, a signal processing circuit formed on the silicon substrate 300 together with the light receiving device may be a MOS (Metal-Oxide-Semiconductor) transistor and a BiCMOS (Bipolar CMOS) other than the bipolar transistor.

(FIFTH EMBODIMENT)

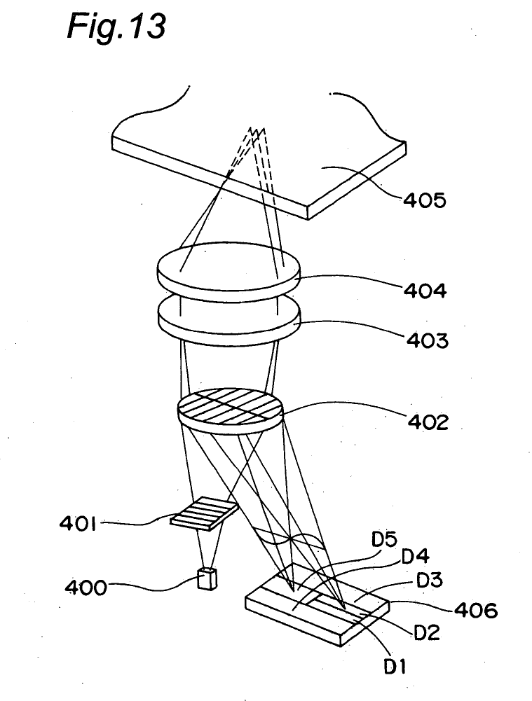

FIG. 13 is a view showing an optical pickup provided in the optical disk drive in the fifth embodiment of the present invention. The optical pickup splits light with wavelength of approx. 400 nm emitted by a semiconductor laser 400 into three beams, consisting of two side beams for tracking and one main beam for reading signals, with use of a diffraction grating 401 for generating tracking beams. After transmitted through a hologram 402 as zero-order light and converted to parallel light by a collimate lens 403, these beams are collected on a disk 405 by an object lens 404. The light collected on the disk 405 is reflected with light power being modulated by a pit formed on the disk 405, and after this reflected light transmits through an object lens 404 and the collimate lens 403, the light is diffracted by the hologram 402. A first-order optic component diffracted by the hologram 402 comes incident to a split type light receiving device 406 having five light receiving faces from D1 to D5. Then, calculating the outputs from these five light receiving faces by adding to and subtracting from to each other, a reading signal and a tracking signal are obtained.

The split type light receiving device 406 is a light receiving device of the present invention, and the N type semiconductor layer as a second conductivity type semiconductor layer forming the five light receiving faces has a thickness, i.e., a junction depth larger than the absorption length of the wavelength of incident light from the hologram 402, and has an impurity concentration profile similar to that in FIG. 7. Therefore, the split type light receiving device 406 has impurity concentration at a depth almost equal to the absorption length of the incident light of not larger than 1E19 cm⁻³, which provides excellent sensitivity. Further, the split type light receiving device 406 has a junction depth larger than the absorption length of incident light, so that the resistance is as low as about 50 Ω/sq., by which excellent response speed is attained. Therefore, the split type light receiving device 406 has excellent sensitivity and response speed, so that the optical pickup is suitable for read and write access to high-density optical disks.

In the present embodiment, the optical pickup may adopt other optical systems other than the optical system shown in FIG. 13.

Further, the semiconductor laser 400 may emit light with wavelength other than that of about 400 nm.

1. A light receiving device comprising:
a first conductivity type semiconductor layer; and
a second conductivity type semiconductor layer on the first conductivity type semiconductor layer, wherein
a thickness of the second conductivity type semiconductor layer is larger than an absorption length of light to be received incident to the second conductivity type semiconductor layer, and
the second conductivity type semiconductor layer has an impurity concentration of not smaller than 1E17 cm⁻³ and not larger than 1E19 cm⁻³ in a vicinity of a surface of the second conductivity type semiconductor layer.

2. A light receiving device as defined in claim 1, wherein:
the second conductivity type semiconductor layer has said impurity concentration at a position which is at a distance from the surface of the second conductivity type semiconductor layer in a thickness direction, said distance being almost equal to the absorption length of the light.

3. The light receiving device as defined in claim 1, wherein
the second conductivity type semiconductor layer has a peak impurity concentration on the surface.

4. A light receiving unit incorporating a circuit comprising:
a light receiving device, comprising:
a first conductivity type semiconductor layer; and
a second conductivity type semiconductor layer on the first conductivity type semiconductor layer, wherein
a thickness of the second conductivity type semiconductor layer is larger than an absorption length of light to be received incident to the second conductivity type semiconductor layer, and
the second conductivity type semiconductor layer has an impurity concentration of not smaller than 1E17 cm⁻³ and not larger than 1E19 cm⁻³ in a vicinity of a surface of the second conductivity type semiconductor layer; and
a signal processing circuit for processing a signal from the light receiving device, wherein
the light receiving device and the signal processing circuit are formed on an identical substrate.

5. An optical disk drive comprising:
a light receiving device, the light receiving device comprising:
a first conductivity type semiconductor layer; and
a second conductivity type semiconductor layer on the first conductivity type semiconductor layer, wherein
a thickness of the second conductivity type semiconductor layer is larger than an absorption length of light to be received incident to the second conductivity type semiconductor layer, and
the second conductivity type semiconductor layer has an impurity concentration of not smaller than 1E17 cm⁻³ and not larger than 1E19 cm⁻³ in a vicinity of a surface of the second conductivity type semiconductor layer.

6. An optical disk drive comprising:
a light receiving unit incorporating a circuit comprising:
a light receiving device, comprising:
a first conductivity type semiconductor layer; and
a second conductivity type semiconductor layer on the first conductivity type semiconductor layer, wherein
a thickness of the second conductivity type semiconductor layer is larger than an absorption length of light to be received incident to the second conductivity type semiconductor layer, and
the second conductivity type semiconductor layer has an impurity concentration of not smaller than 1E17 cm⁻³ and not larger than 1E19 cm⁻³ in a vicinity of a surface of the second conductivity type semiconductor layer; and
a signal processing circuit for processing a signal from the light receiving device, wherein
the light receiving device and the signal processing circuit are formed on an identical substrate.

7. A light receiving device comprising:
a first semiconductor layer having a first conductivity type;
a second semiconductor layer having a second conductivity type formed on the first semiconductor layer; and
a third semiconductor layer having the second conductivity type formed on the second semiconductor layer, wherein
a thickness of the third semiconductor layer is larger than an absorption length of light to be received incident to the third semiconductor layer, and
the third semiconductor layer has an impurity concentration of not smaller than 1E17 cm⁻³ and not larger than 1E19 cm⁻³ in a vicinity of a surface of the third semiconductor layer.

8. The light receiving device as defined in claim 7, wherein
the third semiconductor layer has said impurity concentration at a position which is at a distance from the surface of the third semiconductor layer in a thickness direction, said distance being almost equal to the absorption length of the light.

9. The light receiving device as defined in claim 7, wherein
the third semiconductor layer has a peak impurity concentration on the surface.

10. A light receiving unit incorporating a circuit comprising:
a light receiving device including:
a first semiconductor layer having a first conductivity type;
a second semiconductor layer having a second conductivity type formed on the first semiconductor layer; and
a third semiconductor layer having the second conductivity type formed on the second semiconductor layer, wherein
a thickness of the third semiconductor layer is larger than an absorption length of light to be received incident to the third semiconductor layer, and
the third semiconductor layer has an impurity concentration of not smaller than 1E17 cm⁻³ and not larger than 1E19 cm⁻³ in a vicinity of a surface of the third semiconductor layer; and
a signal processing circuit for processing a signal from the light receiving device, wherein
the light receiving device and the signal processing circuit are formed on an identical substrate.

11. An optical disk drive comprising:
a light receiving device including:
a first semiconductor layer having a first conductivity type;
a second semiconductor layer having a second conductivity type formed on the first semiconductor layer; and
a third semiconductor layer having the second conductivity type formed on the second semiconductor layer, wherein
a thickness of the third semiconductor layer is larger than an absorption length of light to be received incident to the third semiconductor layer, and
the third semiconductor layer has an impurity concentration of not smaller than 1E17 cm⁻³ and not larger than 1E19 cm⁻³ in a vicinity of a surface of the third semiconductor layer.

12. An optical disk drive comprising:
a light receiving unit incorporating a circuit comprising:
a light receiving device including:
a first semiconductor layer having a first conductivity type;
a second semiconductor layer having a second conductivity type formed on the first semiconductor layer; and
a third semiconductor layer having the second conductivity type formed on the second semiconductor layer, wherein
a thickness of the third semiconductor layer is larger than an absorption length of light to be received incident to the third semiconductor layer, and
the third semiconductor layer has an impurity concentration of not smaller than 1E17 cm⁻³ and not larger than 1E19 cm⁻³ in a vicinity of a surface of the third semiconductor layer; and
a signal processing circuit for processing a signal from the light receiving device, wherein
the light receiving device and the signal processing circuit are formed on an identical substrate.
